(19) United States
(12) Patent Application Publication
(10) Pub. No.: US 2005/0263903 A1
(43) Pub. Date: Dec. 1, 2005

(54) Method for pattern metalization of substrates

(75) Inventors: Charles Forbes, Vineland, NJ (US); Alexander Gelbman, West Orange, NJ (US); Christopher Turner, Belmont, MA (US); Helena Gleskova, Princeton, NJ (US); Sigurd Richard Wagner, Princeton, NJ (US)

Correspondence Address: LAHIVE & COCKFIELD, LLP., 28 STATE STREET, BOSTON, MA, 02109, US

(73) Assignee: Visible Tech-knowledgy, Inc., Hoboken, NJ (US)

(21) Appl. No.: 11/070,139

(22) Filed: Mar. 1, 2005

Related U.S. Application Data
(63) Continuation-in-part of application No. 10/931,154, filed on Aug. 30, 2004.
(60) Provisional application No. 60/498,983, filed on Aug. 30, 2003.
(60) Provisional application No. 60/550,091, filed on Mar. 4, 2004.

(51) Int. Cl. H01L 21/00; H01L 29/40; H01L 23/52; H01L 23/48; B32B 15/00; B32B 7/00; B32B 3/00; H01L 21/84

(52) U.S. Cl. 257/763; 438/149

(57) ABSTRACT

The present invention provides a method for forming an adhesion layer in contact with a first surface of a substrate and a surface of a layer having electrically conductive properties using electrophotographic imaging compound as a mask. The adhesion layer improves the lamination properties of the electrically conductive layer to the substrate. The improved lamination properties to facilitate and increase the reliability and quality of a resulting product having an electronic circuit formed in accordance with the present invention. The method disclosed herein is well suited for use with rigid polymeric substrates and flexible polymeric substrates.

### RELATED APPLICATION

This application is a continuation in part U.S. Non-Provisional Application Ser. No. 10/931,154 filed Aug. 30, 2004, which claims priority to Provisional Application Ser. No. 60/498,983, filed Aug. 30, 2003, the contents of which are hereby incorporated by reference, and claims priority to Provisional Application Ser. No. 60/550,091, filed Mar. 1, 2004, the contents of which are hereby incorporated by reference.

### BACKGROUND OF THE INVENTION

The present invention is directed to the formation of structural features on a substrate, and is more particularly directed to formation of a transistor on a flexible polymeric substrate.

Conventional photolithographic patterning techniques used in patterning wafers tends to be time consuming and costly. A significant portion of the cost and time associated with conventional photolithography is the development and fabrication of a mask. Another significant portion of the costs relate to investment costs, for example, capital equipment (e.g. a mask aligner) and higher material costs especially for photomasks and photoresists. Other significant costs contributing to the total costs of using photolithography as a patterning technique are associated with material handling, for example, material collection and disposal for waste solvents and photoresist.

Recent developments in integrated circuit fabrication techniques have reduced or overcome the burdens of long lead times and fabrication costs associated with the use of conventional masks. Such developments include electrophotographic imaging techniques for pattern formation, contact hole opening, and device isolation on a substrate. Electrophotographic imaging techniques use an image forming apparatus to apply electrophotographic imaging compounds, such as dry toner, to a substrate. The application of the electrophotographic imaging compounds to the substrate forms a mask suitable for use in forming structural patterns or features of an integrated circuit. As with most electrophotographic imaging techniques the desired pattern is first created on an electronic device, such as a computer and when completed, is transferred to the image forming apparatus for imaging on a selected medium or substrate. Masks of electrophotographic imaging compounds toner have been applied to glass substrates, polymeric substrates, both flexible and in rigid polymeric with modest success.

One burden of forming a mask with an electrophotographic imaging compound on a polymeric substrate is the adhesion of an initial conductive layer in a stack-up to a surface of the polymeric substrate. More specifically, the initial conductive layer in contact with the polymeric substrate tends to delaminate therefrom. This fact is particularly burdensome when the polymeric substrate is a flexible polymeric substrate.

The delamination of the initial conductive layer in contact with the surface of the polymeric substrate causes entire portions of stack up to lift from the substrate introducing quality and reliability issues in electronic goods. There accordingly exists a need in the art for improving the adhesion of an initial conductive layer in a stack-up of an integrated circuit or an electronic circuit to a polymeric substrate.

### SUMMARY OF THE INVENTION

The present invention addresses the above described limitations of forming an integrated circuit or an electronic circuit on a polymeric substrate. A method and electronic circuit is described herein that provides an approach to form an adhesion layer in contact with a surface of the polymeric substrate and a surface of a first conductive layer to improve the adhesion of the first conductive layer of the electronic circuit or integrated circuit to the polymeric substrate.

In one illustrative embodiment of the present invention, a method for forming a conductive element on a first surface of a substrate is disclosed. The method includes steps of forming an adhesion layer on a portion of the first surface of the substrate and forming the conductive element on the adhesion layer. The method can further include a step of forming a mask of an electrophotographic imaging compound on the first surface of the substrate and heating the substrate with the mask formed thereon to an elevated temperature for a selected period of time.

The method can further include a step of removing at least a portion of the mask from the first surface of the substrate. In one aspect of the present invention, a stiffener is provided and the substrate is affixed thereto to stiffen the substrate during the step of forming the mask on the selected surface of the substrate and if desired to stiffen the substrate during the formation of the adhesion layer, and if desired during formation of the conductive element on the adhesion layer.

The method can also include steps to form a double sided electronic circuit. By performance of the steps of forming, an adhesion layer on a portion of a second surface of the substrate and forming a conductive element on the adhesion layer formed on the second surface of the substrate the present invention is well suited for use in producing double sided electronic circuits.

The method disclosed herein can further include a step of forming a dielectric layer on a portion of the first surface of the substrate. The dielectric layer can include silicon nitride (SiNₓ), silicon nitride (Si₃N₄), silicon dioxide (SiO₂) or another suitable material for use as a dielectric layer. Suitable methods for forming the adhesion layer include, but are not limited to electron deposition, thermal deposition, sputtering, plasma deposition, plating, either with an electrode or in an electrodeless manner, spraying, or other suitable technique. A substrate suitable for use with the method of the present invention can be rigid or flexible and can include materials such as one or more polymers, glass, silicon, lignocellulosic, fabric or other conventional substrate material such as gallium arsenide (GaAs) and variations thereof.

In another illustrative embodiment of the present invention, an electronic circuit is disclosed. The electronic circuit includes a substrate, an adhesion layer in contact with a portion of a first surface of the substrate, and a conductive path in contact with a portion of the adhesion layer. The conductive path couples a portion of a first electronic device of the electronic circuit to a second portion of a second electronic device of the electronic circuit.

The electronic circuit can further include a dielectric layer in contact with a portion of the substrate and a portion of the adhesion layer. Further, the electronic circuit can be a double sided electronic circuit with an adhesion layer in contact with a portion of a second surface of a polymeric substrate and a conductive path in contact with a portion of the adhesion layer in contact with the portion of the second surface of the substrate. The conductive path couples a portion of a third electronic device of the electronic circuit to a fourth electronic device of the electronic circuit.

In one illustrative embodiment of the present invention a method for forming a transistor on a flexible substrate is disclosed. The method includes the steps of imaging the flexible substrate with an image forming apparatus to form a plurality of masks and forming a gate, a drain, and a source of the transistor on the flexible substrate according to the features defined by the plurality of masks. Each of the masks define one or more features of the transistor.

The method can further include a step of forming a first insulator layer on a first surface of the flexible substrate. The method can further include an additional step of forming a second insulator layer on a second surface of the flexible substrate. Further, the method can include a step of removing at least a portion of each of the masks to expose desired features of the transistor.

The method can further include the steps of affixing the substrate to a stiffener and forming a plurality of metallized layers on the flexible substrate to form a plurality of contact regions.

In another illustrative embodiment of the present invention, a method for forming an array of transistors is disclosed. Performance of the method forms a first metallized layer on a portion of a first surface of a flexible substrate. Further performance of the method forms a first dielectric layer on a portion of the first surface of the flexible substrate and on a plurality of surfaces of the first metallized layer. Still further, performance of the method forms a first conductor layer on a surface of the first dielectric layer and forms a second conductive layer on a portion of a surface of the first conductive layer. Further performance of the method forms a second metallized layer on portions of the second conductive layer.

The method can further include the steps of forming a first insulator layer on a first surface of the flexible substrate and forming a second insulator layer on a second surface of the flexible substrate.

In one embodiment of the present invention, a method for forming a conductive element on a lignocellulosic substrate is disclosed. The method includes steps of forming a mask of an electrophotographic compound on a lignocellulosic substrate defining a conductive element and forming the conductive element on the lignocellulosic substrate as defined by the mask. The method can further include the step of forming an adhesion layer on the lignocellulosic substrate as defmed by the mask.

In another embodiment of the present invention, an electronic circuit is disclosed. The electronic circuit includes a lignocellulosic substrate, an adhesion layer in contact with a portion of the first surface of the lignocellulosic substrate, and a conductive path in contact with a portion of the adhesion layer. The conductive path couples a portion of a first electronic device of the electronic circuit to a portion of a second electronic device of the electronic circuit.

In another embodiment of the present invention, an electronic display is disclosed. The electronic display includes an electrophotographically imaged backplane formed on a lignocellulosic substrate, an electrophoretic display medium coupled to the electrophotographically imaged backplane, and a common electrode coupled to the electrophoretic display medium.

### BRIEF DESCRIPTION OF THE DRAWINGS

The foregoing and other objects, features and advantages of the invention will be apparent from the following description and apparent from the accompanying drawings, in which like reference characters refer to the same parts throughout the different views. The drawings illustrate principals of the invention and, although not to scale, show relative dimensions.

FIG. 1 is a block diagram illustrating an exemplary environment suitable for creating a mask and imaging the mask on a substrate in accordance with the teachings of the present invention.

FIG. 2 is a block diagram illustrating a suitable environment for forming the adhesion layer and the conductive element on the substrate in accordance with the teachings of the present invention.

FIG. 3 is a top view of a substrate having formed thereon a mask in accordance with the teachings of the present invention.

FIG. 4 is a side view of the substrate in FIG. 3 illustrating the mask formed thereon in accordance with the teachings of the present invention.

FIG. 5 is a side view of the substrate in FIG. 3 illustrating an adhesion layer formed thereon in accordance with the teachings of the present invention.

FIG. 6 is a side view of the substrate in FIG. 3 illustrating a conductive element formed thereon in accordance with the teachings of the present invention.

FIG. 7 is a side view of the substrate in FIG. 3 illustrating the substrate after cleaning to remove the mask and any overlying material layer in accordance with the teachings of the present invention.

FIG. 8 is a block flow diagram illustrating steps taken to perform one illustrative embodiment of the present invention.

FIG. 9 is a block flow diagram illustrating steps taken to perform a second illustrative embodiment of the present invention.

FIG. 10 illustrates a side view of a substrate having an inorganic substance coated on the top surface and bottom surface in accordance with the teachings of the present invention.

FIG. 11 illustrates a first double sided electronic circuit formed in accordance with the teachings of the present invention.

FIG. 12 illustrates a second double sided electronic circuit formed in accordance with the teachings of the present invention.

FIG. 13 illustrate a side view of a portion of an electronic display having and electronic circuit formed in accordance with the teachings of the present invention.

FIG. 14 illustrates a substrate material suitable for use in practicing the illustrative embodiment of the present invention.

FIG. 15 illustrates a side view of an exemplary transistor formed in accordance with the teachings of the present invention.

FIG. 15A illustrates a side view of an exemplary transistor having an adhesion layer formed in accordance with the teachings of the present invention.

FIG. 16 is an exemplary side view of another transistor formed in accordance with the teachings of the present invention.

FIG. 16A is an exemplary side view of another transistor having an adhesion layer formed in accordance with the teachings of the present invention.

FIG. 17 provide a block flow diagram of steps taken to form transistors depicted in FIGS. 15 and 16 in accordance with the teachings of the present invention.

FIG. 18 illustrates an exemplary mask suitable for use in forming the transistors depicted in FIGS. 15 and 16.

FIG. 19 depicts a second exemplary mask suitable for use in accordance with the teachings of the present invention to form the transistors depicted in FIGS. 15 and 16.

FIG. 20 depicts a third exemplary mask suitable for use in accordance with the teachings of the present invention to form the transistors illustrated in FIGS. 15 and 16.

FIG. 21 depicts a fourth exemplary mask suitable for use in accordance with the teachings of the present invention to form the transistors depicted in FIGS. 15 and 16.

FIG. 22 provides a graphical representation of the I-V characteristics of the transistor depicted in FIG. 15.

FIG. 23 provides a graphical representation of the I-V characteristics of the transistor depicted in FIG. 16.

FIG. 24 illustrates a lignocellulosic substrate suitable for use in forming a display in accordance with the teachings of the present invention.

FIG. 25 illustrates a portion of the mask depicted in FIG. 27 formed on a surface of the lignocellulosic substrate in FIG. 24 in accordance with the teachings of the present invention.

FIG. 26 illustrates a portion of the conductive layer defined by the mask in FIG. 27 formed on a surface of the lignocellulosic substrate in FIG. 24 in accordance with the teachings of the present invention.

FIG. 27 illustrates a mask suitable for use in forming a seven segment display in accordance with the teachings of the present invention.

FIG. 28 illustrates an exploded view of a display formed in accordance with the teachings of the present invention.

### DETAILED DESCRIPTION

The present invention is directed to an electronic circuit having an adhesion layer in contact with a surface of a substrate and a surface of a conductive element and to a method for forming the adhesion layer and the conductive element on the substrate. The formation of the adhesion layer is accomplished by imaging a mask of an electrophotographic imaging compound onto a substrate using an image forming apparatus, and forming the adhesion layer on the mask and the substrate, and, in turn, forming the conductive element on the adhesion layer. The mask provides the desired structural pattern for the resulting conductive element. The adhesion layer is formed from a material, for example, titanium (Ti), chromium (Cr), nickel (Ni), aluminum (Al), copper (Cu), silicon dioxide (SiO₂), silicon nitrate (SiNₓ), or other suitable material or compound having properties or a structure well suited for adhering to a surface of a selected substrate type. In this manner, the conductive element adheres to the adhesion layer, which, in turn adheres to the surface of the substrate to provide an approach that improves the lamination of a conductive element to a substrate surface in an electronic circuit.

Before proceeding with the remainder of the detailed description, it is first helpful to define a few terms used throughout the disclosure.

As used herein, the term “image forming apparatus” refers to an apparatus or device for depositing on a medium an electrophotographic imaging compound.

Examples of an image forming apparatus include, but are not limited to, a laser printer, a xerographic imaging device, a facsimile machine, and other like apparatuses or devices that form an image on a medium using electrophotographic imaging compounds.

As used herein, the term “conductive element” refers to a conductive path, a portion of a conductive path, an electronic device, or a portion of an electronic device, formed from a conductive or semiconductive material or compound. The conductive path or portion of a conductive path provides a transmission medium capable of transmitting an analog signal, a digital signal, or a power signal alone or as part of a power grid, or as a conductive path to ground or a portion of a ground plane.

As used herein, the term “electronic device” refers a transistor, a portion of a transistor such as a gate, drain or source, an inductor, a capacitor, or a resistor.

As used herein, the term “organic solvent” includes any non-aqueous solution chosen from the ketone group, such as acetone, methylisobutyl ketone; the aromatic solvent group, such as toluene, xylene; the ester group, such as ethyl acetate, methoxyproply acetate; the ether group, such as diethyl ether; and other solvents such as dimethyl formamide, N-methylpyrolidone, or gamma-butyrolactone.

As used herein, the term “substrate” refers to a rigid substrate with little or no ability to flex in any number of dimensions or to a substrate having properties that allow the substrate to flex (i.e. conformable) in a plurality of dimensions. Examples of substrates include, but are not limited to, silicon substrates, glass substrates, glass foil substrates, polymeric substrates, gallium arsenide substrates, indium phosphate, and other like substrates. Examples of electrophotographic patterning on glass foil are discussed in detail in U.S. Pat. No. 6,080,606, entitled “Electrophotographic Patterning of Thin Film Circuits”, the contents of which are incorporated herein by reference.

As used herein, the term “polymeric substrate” or “flexible polymeric substrate” includes such polymers as polyimides, polyvinyls, polybenzimideazoles, polyesters, polyacrylates, polyamides, polybenzimidazole, celluloid, or other polymers suitable for use in the fabrication of an electronic circuit.

As used herein, the term “material source” includes such material sources as electron beam systems, thermal evaporation systems, chemical vapor deposition tools, enhanced chemical vapor deposition tools, sputtering systems, spray systems, platting systems including electrode platting systems and electrodeless plating systems and other like systems capable of depositing one or more selected materials of compounds on a substrate.

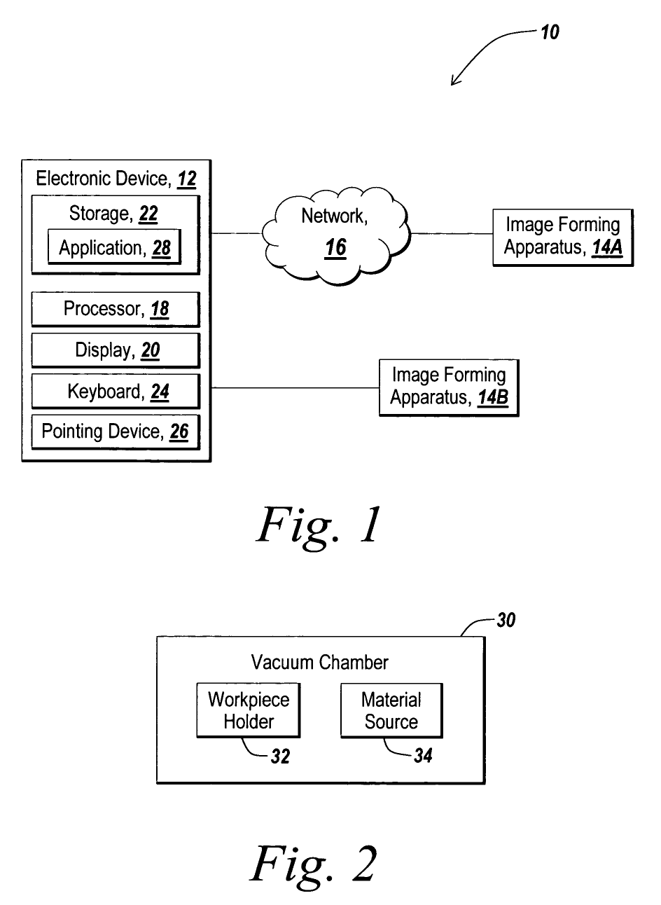

FIG. 1 illustrates an environment suitable for creating a mask and imaging the mask on a substrate in accordance with the teachings of an illustrative embodiment of the present invention. A computer system 10 includes an electronic device 12, a network 16, such as the Internet, an intranet, or other suitable network, either wired or wireless, or a hybrid of wired and wireless, and an image forming apparatus 14A. Alternatively, or in addition to, the computer system 10 can include image forming apparatus 14B coupled directly to electronic device 12 through a cable or other medium capable of handling serial data, parallel data or both.

The electronic device 12 includes a processor 18 for executing various instructions and programs, and controlling various hardware and software components. The electronic device 12 also includes a display device 20 for use in rendering textual and graphical images, a storage device 22 for storing various items such as data, information, and programs. A keyboard 24 and a pointing device 26 are also included with the electronic device 12. The pointing device 26 includes such devices as a mouse, track ball, or light pen. Those skilled in the art will recognize that the pointing device 26 can be incorporated with the display device 22 to provide the electronic device 12 with a touch screen that allows the user to interact with the electronic device 12 with a stylist or with other means such as a user's finger.

The storage device 22 includes an application 28 for use in creating and developing masks having a desired graphical or structural pattern. One suitable application for use in creating or developing a mask in accordance with the illustrative embodiment of the present invention is Adobe® PostScript® available from Adobe Systems Incorporated, of San Jose, Calif. Nevertheless, those skilled in the art will recognize that other suitable applications are available for use in creating or developing a mask in accordance with the illustrative embodiment of the present invention for example, other such applications can include, but are not limited to, CorelDRAW® available from Corel Corporation of Ottawa, Canada; and Adobe® Photoshop® available from Adobe Systems Incorporated, of San Jose, Calif. Those skilled in the art will recognize that the electronic device 12 includes other software such as, various user interfaces and other programs, such as one or more OS programs, compilers, drivers, and various other program applications developed in a variety of programming environments for controlling system software and hardware components.

FIG. 2 illustrates an exemplary environment for forming the adhesion layer and the conductive element on the substrate in accordance with the teachings of the present invention. Vacuum chamber 30 includes workpiece holder 32 and a material source 34. The workpiece holder 32 has a structure for holding a substrate having formed thereon a mask during formation of an adhesion layer and a conductive element according to the structural pattern defined by the mask. The material source 34 deposits the material or materials selected for the adhesion layer and the conductive element as defined by the mask. One suitable material source for use in practicing the illustrative embodiment of the present invention includes a Denton electron beam evaporator available from Denton Vacuum of Moorestown, N.J. Those skilled in the art will appreciate that vacuum chamber 30 can include other equipment including a mechanical scanner or an electrostatic scanner, vacuum pumps, water cooling elements and one or more control systems for controlling operation of the vacuum chamber and the material source 34.

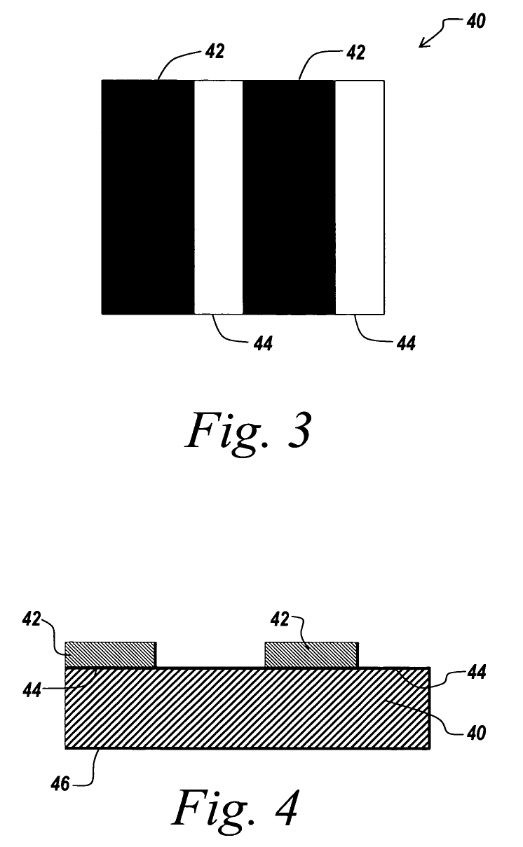

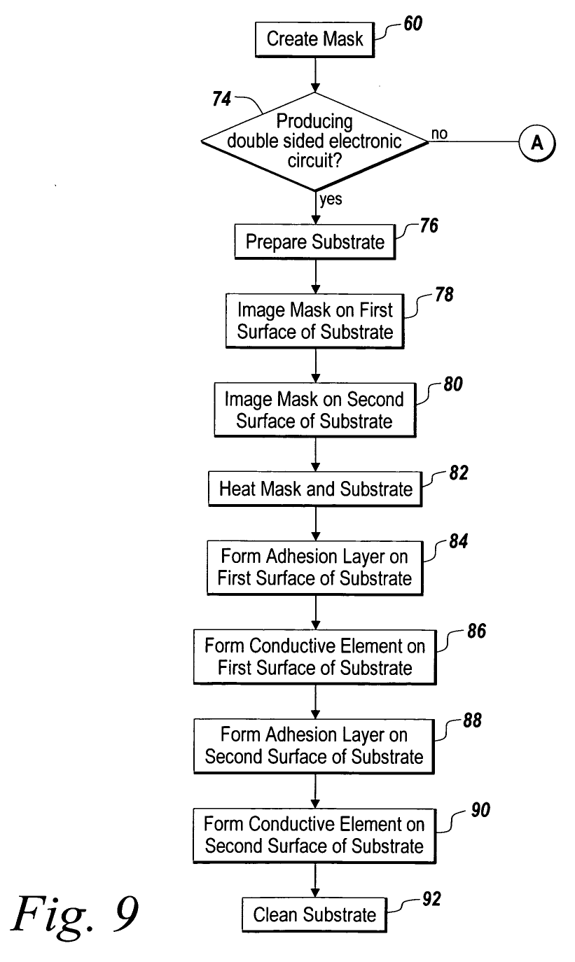

FIG. 3 illustrates a top view of a substrate 40 having formed on a first surface 44, a mask 42. Those skilled in the art will appreciate that the illustration of mask 42 is meant to facilitate explanation of the present invention and the mask 42 can take the form of any desired graphical shape capable of being formed by the application 28 and the image forming apparatus 14A or 14B. Moreover, those skilled in the art will appreciate that the line width or resolution of the mask formed with system 10 is a function of the particle size of the electrophotographic imaging compound used and the resolution (dpi) of the image forming apparatus. As illustrated in FIG. 3, the mask 42 represents a negative resist mask. As such, portions of the first surface 44 of the substrate 40 covered with the mask 42 will be free of additional layers formed thereon upon removal or cleaning of the mask 42 from the first surface 44. The steps taken to form the elements illustrated in FIGS. 3-7 are discussed in detail with regard to FIGS. 8 and 9.

FIG. 4 illustrates a side view of the substrate 40 having formed thereon the mask 42 as illustrated in FIG. 3.

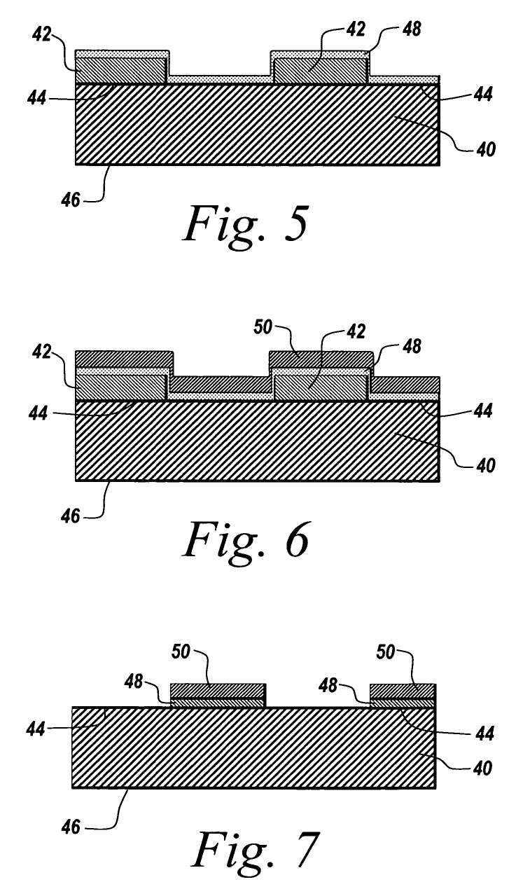

FIG. 5 illustrates a side view of the substrate 40 having formed on the first surface 44 an adhesion layer 48. As illustrated, the adhesion layer 48 contacts a portion of the first surface 44 of the substrate 40 free of the mask 42, and contacts the mask 42. The substrate 40 includes a second surface 46 suitable for use in forming a double sided electronic device, which will be discussed in more detail with regard to FIGS. 9, 11, and 12.

FIG. 6 illustrates a side view of the substrate 40 having formed on the first surface 44, the mask 42, the adhesion layer 48, and conductive element 50.

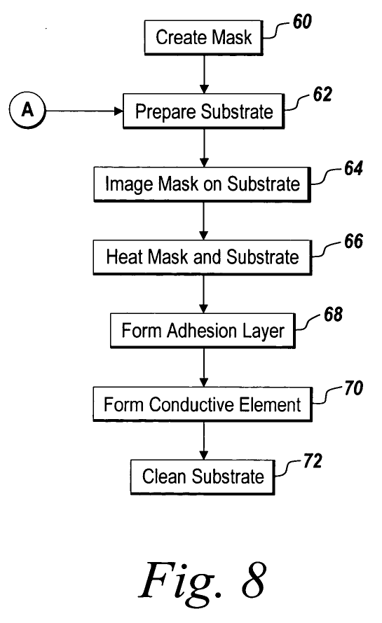

FIG. 7 illustrates the substrate 40 following completion of a cleaning or removal process to remove the mask 42 therefrom. Upon removal of the mask 42 a portion of the first surface 44 of substrate 40 previously covered by the mask 42 is free of the mask 42 and overlying layers, such as the adhesion layer 48 and the conductive element 50. Likewise, portions of the adhesion layer 48 and the conductive element 50 remain affixed to those portions of the first surface 44 of the substrate 40 where no mask 42 was formed on the first surface 44 of the substrate 40. The remaining adhesion layer 48 and conductive element 50 have a structure and pattern defined by the mask 42.

FIG. 8 illustrates the steps taken to form the structure illustrated in FIG. 7. In step 60, a user of computer system 10 creates the mask 42. In step 62, the user prepares the substrate 40 for imaging the mask 42 thereon. Preparation of the substrate 42 can include, but is not limited to, cleaning a surface of the substrate 40, affixing the substrate 40 to a stiffener, such as a sheet of paper or other suitable medium, or coating a surface of the substrate 40 with a dielectric. Suitable dielectrics include, but are not limited to silicon nitride (SiNₓ), silicon nitride (Si₃N₄), or silicon dioxide (SiO₂). The thickness of a precoat dielectric can be up to about 500 nm.

In step 64, image forming apparatus 14A or 14B forms on the substrate 40 the mask 42. The image forming apparatus 14A or 14B receives the image of the mask 42 from the application 28. The formation of the mask 42 in step 64 can occur on a clean substrate 40 free of a dielectric layer or on the substrate 40 with a dielectric layer.

In step 66, the substrate 40 and the mask 42 are heated to an elevated temperature, for example in an oven. The elevated temperature is between about 100° C. and about 150° C. The period of heating the substrate 40 and the mask 42 can range between about 1 second and about 2000 seconds.

In step 68, the adhesion layer 48 is formed. Formation of the adhesion layer 48 takes place in the vacuum chamber 30 using the material source 34. Material source 34 deposits on a surface of the substrate 40 and the mask 42 a selected material or compound to form the adhesion layer 48. Such suitable material sources include, but are not limited to sputterers, spraying apparatuses, electron beam evaporators, thermal evaporators, electrode platters, and electrodeless platters. The material or compound selected to form the adhesion layer 48 can be a conductive or semiconductive material. Suitable materials for use as the adhesion layer 48 include, but are not limited chromium (Cr), nickel (Ni), titanium (Ti), aluminum (Al), copper (Cu), silicon dioxide (SiO₂), and silicon nitride (SiNₓ). Suitable thicknesses of the adhesion layer 48 can range between about 50 Angstroms to about 100 Angstroms or about 5 nanometers to about 10 nanometers. Those skilled in the art will appreciate that the material composition of the adhesion layer 48 can have the same chemical composition as a dielectric layer used to precoat a surface of substrate 40.

In step 70, the conductive element 50 is formed in the vacuum chamber 30 using the material source 34 as the workpiece holder 32 holds the substrate 40. Material source 34 deposits on a surface of the adhesion layer 48 a selected material or compound to form the conductive element 50. Such suitable material sources include, but are not limited to sputterers, spraying apparatuses, electron beam evaporators, thermal evaporators, chemical vapor deposition tools, enhanced chemical vapor deposition tools, electrode platters, and electrodeless platters. The material or compound selected to form the conductive element 50 can be a conductive or semiconductive material. Suitable materials for use as the conductive element 50 include, but are not limited chromium (Cr), nickel (Ni), copper (Cu), aluminum (Al), titanium (Ti), gold (Au), copper (Cu), silicon dioxide (SiO₂), or other material or compound. Suitable thicknesses of the conductive element 50 can range between about 50 Angstroms to about 1000 Angstroms or about 5 nanometers to about 100 nanometers.

In step 72, the substrate 40 is cleaned using a suitable cleaning technique to remove mask 42 from the substrate 40. Those skilled in the art will recognize there exist a number of suitable cleaning techniques to remove the mask 42 at any time after the formation of the conductive element 50. Moreover, those skilled in the art will recognize that the suitable cleaning techniques may be combined in a number of manners to facilitate the cleaning process. Examples of cleaning techniques include, but are not limited to, ultrasonic cleaning, rubbing with a swab, pulse jet sprays. Any or all of these techniques can be used alone or in combination with solvents such as 1,1,1-trichloroethane (TCE), solvents from the ketone group, such as acetone, methylisobutyl ketone; the aromatic solvent group such as toluene, xylene; the ester group, such as ethyl acetate, methoxypropyl acetate; ether group such as diethyl ether, and other commonly used solvents such as dimethyl formamide, N-methylpyrolidone, or gamma-butyrolactone.

FIG. 9 illustrates steps taken to form a double sided electronic circuit in accordance with the teachings of the present invention. In step 60, mask 42 is created using computer system 10. In step 74, it is decided if the electronic circuit is double sided. Those skilled in the art will recognize that the decision to form a double sided electronic circuit can take place before or during step 60, creation of the mask. If the electronic circuit is a single sided electronic circuit or it is decided to process a double sided electronic circuit one side at a time the process proceeds to step 62 in FIG. 8. If in step 74, it is decided to produce a double sided electronic circuit, the process flows to step 76 in which the substrate is prepared. Those skilled in the art will appreciate that steps 76-92 parallel and are analogous to steps 62-72 detailed in connection with FIG. 8. Moreover, those skilled in the art will recognize that in the formation of a double sided electronic circuit a first side of the substrate 40 can be formed according to the teachings of the present invention before the second surface of the substrate 40 is process to fabrication the second side of the double sided electronic circuit. Furthermore, those skilled in the art will appreciate that the structural elements of the electronic circuit formed on the first surface of the substrate 40 and the structural elements of the electronic circuit formed on the second surface of the substrate 40 can be formed in alternating fashion so that in one step the mask is formed on the first surface and in a next step the mask is formed on a second surface and so on until the desired double sided electronic circuit is formed on the substrate 40. Further, those skilled in the art will appreciate that the actual sequencing of steps taken are flexible enough to suit any desired processing requirements based on material availability, manpower, and station time in a vacuum chamber to form the various structural components.

In step 78, the computer system 10 images the mask 42 on the first surface 44 of substrate 40 using the image forming apparatus 14A or 14B. In step 80, the computer system 10 forms mask 42 on the second surface 46 of substrate 40 using the image forming apparatus 14A or 14B. Those skilled in the art will appreciate that the mask formed on the first surface 44 of the substrate 40 can define one or more structural features distinct from the mask formed on the second surface 46 of the substrate 40 and vice versa.

In step 82, the substrate 40 and the mask 42 are heated to an elevated temperature for a selected period of time. In step 84, the adhesion layer 48 is formed on the first surface 44 of the substrate 40. In step 86, the conductive element 50 is formed on the adhesion layer 48 of the first surface 44 of the substrate 40. In step 88, the adhesion layer 48 is formed on the second surface 46 of the substrate 40. In step 90, the conductive element 50 is formed on the adhesion layer 48 of the second surface of the substrate 40. In step 92, the processed substrate 40 is cleaned to remove the mask from the first surface 44, the second surface 46, or both.

The adhesion layer 48 enables the fabrication of structures that are otherwise unfeasible to fabricate due to delamination of a conductive layer from a substrate. For example, gold and aluminum have poor adhesion properties and delaminate readily from polymeric surfaces. In accordance with the teachings of the present invention, gold can be deposited on polyester without delamination using an adhesion layer of titanium. The present invention provides an adhesion layer that offers a connective structure between the substrate and the conductive layer. This adhesion layer can also be beneficial in improving electrical properties. For example, chromium deposited directly on a polyimide such as “Kapton® E” using Electron-beam deposition has poor electrical conductivity, whereas Electron-beam deposition of chromium over an adhesive layer of titanium results in improved conductivity. The adhesion layer can also prevent the propagation of cracks in the substrate, an insulating layer in contact with the substrate, and a conductive layer in contact with the insulating layer, or the substrate, or both, during bending, to result in an improvement in the length of a life cycle for flexible circuits.

To illustrate the flexibility and the processing of a substrate according to the teachings of the present invention, seven examples are discussed below in detail.

### EXAMPLE I

A conductive pattern is fabricated on substrate 40 according the teachings of the present invention. Substrate 40 is polyimide (Kapton® E) film having thickness of about 51 μm. The polyimide film is removably attached to an 8½×11 sheet of paper (stiffener) by means of mounting tape. A negative electrophotographic imaging compound pattern is imaged on the polyimide film attached to the sheet of paper as stiffener using a laser printer, for example a Hewlett Packard LaserJet 5P, available from Hewlett Packard of Palo Alto, Calif. The sheet of paper is removed and the electrophotographic imaging compound and the polyimide film are baked in air for about one minute at a temperature of about 120° C. About a 10 nm thick layer of chromium (Cr) is deposited by Electron-beam evaporation on the polyimide film and the electrophotographic imaging compound under vacuum to form an adhesion layer. A layer of titanium (Ti) follows the layer of Cr. The Ti has a thickness of about 100 nm is deposited by Electron-beam evaporation. The polyimide film with the layers of Cr and Ti is placed in an ultrasonic toluene bath and agitated for 1 minute. The ultrasonic bath is repeated once and the polyimide film is washed with 1,1,1 trichloroethane to quantitatively remove electrophotographic imaging compound and overlying metal layers.

### EXAMPLE II

Using a substrate 40 of polyimide (Kapton® E) film having a thickness of about 51 μm a conductive pattern is fabricated thereon. The polyimide film is temporarily attached to a sheet of 8½×11 paper (stiffener) by means of mounting tape. A negative electrophotographic imaging compound pattern is imaged on the polyimide film using a laser printer for example a Hewlett Packard LaserJet 5P, available from Hewlett Packard of Palo Alto, Calif. The sheet of paper is removed from the polyimide film and the electrophotographic imaging compound and the polyimide film are baked in air for about 1 minute at about 120° C. About a 10 nm thick layer of Ti is deposited by Electron-beam evaporation on the polyimide film and the electrophotographic imaging compound under vacuum to form an adhesion layer. Next, about a 100 nm thick layer of gold (Au) is deposited by Electron-beam evaporation on the layer of Ti under vacuum. The polyimide film with the layers of Ti and Au is rubbed with a foam swab in a 1,1,1 trichloroethane/acetone bath to remove the electrophotographic imaging compound and overlying metal layers. The cleaning process is repeated once and the polyimide film is washed with acetone and dried to yield a photographic quality image on polyimide film.

### EXAMPLE III

Using an overhead transparency or a piece of polyester film having a thickness of about 5 mil for substrate 40, a conductive pattern is fabricated as shown in FIG. 7. A negative electrophotographic imaging compound pattern is imaged on the transparency/polyester film using a laser printer, for example a Hewlett Packard LaserJet 5P, available from Hewlett Packard of Palo Alto, Calif. No stiffener is used. The electrophotographic imaging compound and transparency/polyester film is baked in air for about one minute at a temperature of about 120° C. Next, a layer of Ti having a thickness of about 10 nm is deposited on electrophotographic imaging compound and transparency/polyester film the by Electron-beam evaporation under vacuum to form an adhesion layer. The layer of Ti is followed by another Electron-beam evaporation process under vacuum to form a layer of Au having a thickness of about 100 nm on the layer of Ti. The transparency/polyester film with the layer of Ti and Au is lightly rubbed with swabs in a 1,1,1-trichloroethane bath. This cleaning process is repeated once with new solvent and the sample is washed with 1,1,1-trichloroethane to quantitatively remove the layer of electrophotographic imaging compound and overlying metal layers.

### EXAMPLE IV

Using a substrate 40 of polyimide (Kapton® E) film having a thickness of about 51 μm a conductive pattern is fabricated thereon. The polyimide film is temporarily attached to a sheet of 8½×11 paper (stiffener) by means of mounting tape. A negative electrophotographic imaging compound pattern is imaged on the polyimide film using a laser printer, for example a Lexmark Optra S 1255, available from Lexmark International, Inc. of Lexington, Ky. Next, a first layer silicon dioxide (SiO₂) is deposited on the polyimide film and the electrophotographic imaging compound under vacuum using a sputterer to form an adhesion layer. A second layer of SiO₂ is deposited over the first layer of SiO₂ under vacuum using a sputterer. Each layer of SiO₂ has a thickness of about 50 nm. One suitable sputterer for use with the teachings of the present invention is available from AJA International, Inc. of Scituate, Mass. To clean the workpiece, the polyimide film with the two layers of SiO₂ is placed in an ultrasonic toluene bath and agitated for about one minute. The workpiece is then lightly rubbed with swabs in a 1,1,1-trichloroethane bath. This light rubbing process is repeated once with new solvent and the workpiece is washed with 1,1,1-trichloroethane in order to quantitatively remove electrophotographic imaging compound and overlying SiO₂ layers.

### EXAMPLE V

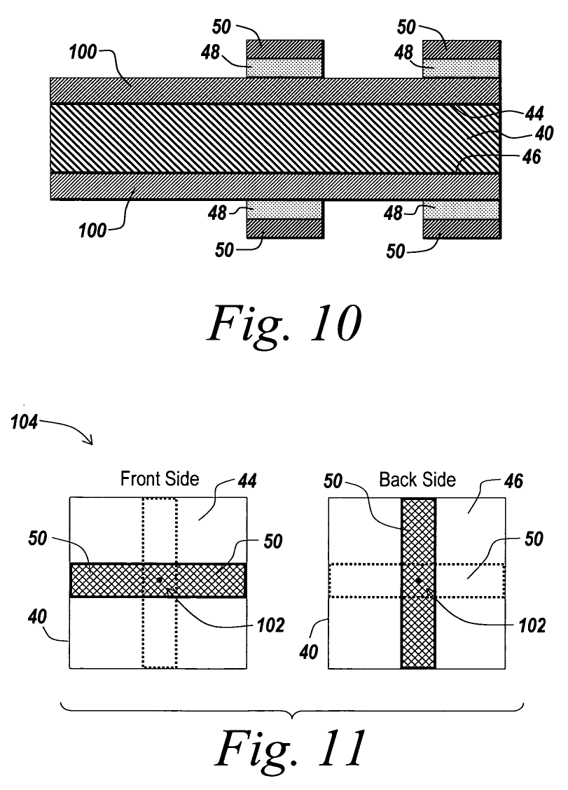

Using a substrate 40 of polyimide (Kapton® E) film having a thickness of about 51 μm a metallized pattern is fabricated thereon. Before imaging the polyimide film with electrophotographic imaging compound, the polyimide film is coated with SiNₓ on a top surface and a bottom surface, as illustrated in FIG. 10. Each coating or layer of SiNₓ has a thickness of about 500 nm. The SiNₓ is deposited on the top surface and the bottom surface of the polyimide using a plasma enhanced chemical vapor deposition (PECVD) tool, for example, using a PECVD tool available from Innovative Systems Engineering of Warminster, Pa. Once coated, the polyimide film is temporarily attached to a sheet of 8½×11 paper (stiffener) by means of mounting tape. A negative electrophotographic imaging compound pattern is imaged on the coated polyimide film using a laser printer, for example a Lexmark Optra S 1255, available from Lexmark International, Inc. of Lexington, Ky. Next, a layer of Cr is deposited on a portion of a first coated surface and the electrophotographic imaging compound pattern to form an adhesion layer. The thickness of the Cr layer is about 10 nm. Formation of the Cr or adhesion layer is followed by deposition of a layer of Ti by Electron-beam evaporation under vacuum. The Ti layer has a thickness of about 100 nm layer. The polyimide film with the coating, the layer of electrophotographic imaging compound, the layer of Cr, and the layer of Ti is placed in an ultrasonic toluene bath and agitated for about one minute. The polyimide film with the various layers is lightly rubbed with swabs in a 1,1,1 trichloroethane bath. This light rubbing process is repeated once with new solvent and the polyimide film is washed with 1,1,1 trichloroethane to quantitatively remove the electrophotographic imaging compound and overlying metal layers.

### EXAMPLE VI

Using a substrate 40 of polyimide (Kapton® E) film having a thickness of about 51 μm a conductive pattern is fabricated thereon. The polyimide film is temporarily attached to a sheet of 8½×11 paper (stiffener) by means of mounting tape. A negative electrophotographic imaging compound pattern is imaged on the polyimide film using a laser printer for example a Hewlett Packard LaserJet 5P, available from Hewlett Packard of Palo Alto, Calif. The sheet of paper is removed from the polyimide film and the electrophotographic imaging compound and the polyimide film are baked in air for about 1 minute at about 120° C. Next, a layer of Cr is deposited by thermal evaporation on a portion of the polyimide film and the electrophotographic imaging compound pattern under vacuum to form an adhesion layer. The layer of Cr has a thickness of about 110 nm. The polyimide film is then rubbed with a foam swab in a 1,1,1 trichloroethane/acetone bath to remove the electrophotographic imaging compound and overlying metal layers. This process is repeated once and the polyimide film is washed with acetone and dried to yield a photographic quality image on polyimide.

### EXAMPLE VII

Using a substrate 40 formed from a 3″×3″ piece polyimide (Kapton® E) film having a thickness of about 51 μm thick a conductive pattern is fabricated thereon. In a center portion of the polyimide film a hole was punched with a punching means, such as a needle, awl, drill or other like punching means to create a via. See FIG. 11. The polyimide film is temporarily attached to a sheet of 8½×11 paper (stiffener) by means of mounting tape. A negative electrophotographic imaging compound pattern consisting of a 0.3 inch horizontal strip as illustrated in FIG. 11 was imaged on the front side of the polyimide film using a laser printer, for example a Lexmark Optra S 1255, available from Lexmark International, Inc. of Lexington, Ky.

Next, a layer of Cr is deposited by Electron-beam evaporation under vacuum on the electrophotographic imaging compound pattern and the front side of the polyimide film to form an adhesion layer. The layer of Cr has a thickness of about 10 nm thick. The layer of Cr is followed by a layer of Ti deposited by Electron-beam evaporation under vacuum. The layer of Ti has a thickness of about 100 nm. The polyimide film with the deposited layers is placed in an ultrasonic toluene bath and agitated for about one minute to remove the electrophotographic imaging compound. The polyimide film is then lightly rubbed with swabs in a 1,1,1 trichloroethane bath. This light rubbing process is repeated once with new solvent and the polyimide film is washed with 1,1,1 trichloroethane to quantitatively remove electrophotographic imaging compound and overlying metal layers from the front surface of the polyimide film.

The polyimide film is turned over and again temporarily attached again to a sheet of paper (stiffener). An electrophotographic imaging compound pattern is imaged on the bottom side of the polyimide using the laser printer. Next, a layer of Cr is deposited by Electron-beam evaporation under vacuum on the electrophotographic imaging compound pattern and the bottom side of the polyimide film to form an adhesion layer on the bottom side. The layer of Cr has a thickness of about 10 nm thick. The layer of Cr is followed by a layer of Ti deposited by Electron-beam evaporation under vacuum. The layer of Ti has a thickness of about 100 nm. The polyimide film is placed in an ultrasonic toluene bath and agitated for about one minute. The polyimide film is lightly rubbed with swabs in 1,1,1 trichloroethane bath. This light rubbing process is repeated once with new solvent and the polyimide film is washed with 1,1,1 trichloroethane to quantitatively remove the electrophotographic imaging compound on the overlying metal layers. Less than 100 Ω resistance was measured between the upper metallization pattern and the lower metallization pattern.

FIG. 10 illustrates the substrate 40 having the first surface 44 and the second surface 46 precoated with an inorganic compound 100. The inorganic compound 100 is applied to one or more surfaces of the substrate 40 prior to the formation of the mask 42 on the substrate 40. Inorganic compound 100, can be a dielectric such as SiNₓ, Si₃N₄, and SiO2 applied on selected surfaces of the substrate 40 and have a thickness of up to about 500 nm. The precoating of a surface of the substrate 40 with the inorganic compound 100 provides a substrate surface that is a barrier to moisture and solvent uptake by the underlying polymer film and can provide adhesion to the subsequent layers. As illustrated in FIG. 10, the adhesion layer 48 is in contact with the inorganic compound 100 and the conductive element 50 contacts a second surface of the adhesion layer 48.

FIG. 11 illustrates a top and bottom view of a double sided electronic circuit 104 formed in accordance with the teachings of the present invention. The electronic circuit 104 includes substrate 40 having formed on the first surface 44 conductive element 50 in contact with adhesion layer 48 (not shown) which, in turn, contacts the first surface 44. Likewise, on the bottom side of the substrate 40 or the second surface 46, the double sided electronic circuit 104 includes the conductive element 50 in contact with the adhesion layer 48 (not shown) which, in turn, is in contact with the second surface 46. Those skilled in the art will appreciate that as illustrated in FIG. 10, the adhesion layer 48 formed on the first surface 44, the second surface 46, or both can be in contact with the inorganic layer 100 formed on the first or second, or both surfaces of the substrate 40. The double sided electronic circuit 104 can include a via 102 to couple the conductive element 50 of the first surface 44 to the conductive element 50 of the second surface 46.

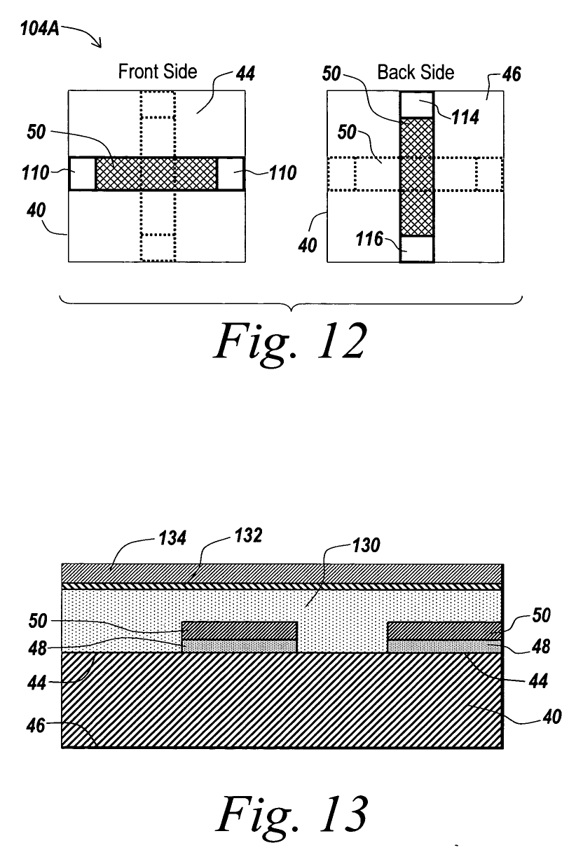

FIG. 12 illustrates a top and bottom view of a double sided electronic circuit 104A formed in accordance with the teachings of the present invention. The electronic circuit 104A includes substrate 40 having formed on the first surface 44 conductive element 50 in contact with adhesion layer 48 (not shown) which, in turn, contacts the first surface 44. The conductive element 50 couples the first electronic device 110 to the second electronic device 112. In this manner, the conductive element 50 is a transmission path for a power signal, an analog signal, or a digital signal. Likewise, on the bottom side of the substrate 40 or the second surface 46, the double sided electronic circuit 104A includes the conductive element 50 in contact with the adhesion layer 48 (not shown) which, in turn, is in contact with the second surface 46. The conductive element 50 on the second surface 46 couples the third electronic device 114 to the fourth electronic device 116. In this manner, the conductive element 50 is a transmission path for a power signal, an analog signal, or a digital signal. Those skilled in the art will appreciate that as illustrated in FIG. 10, the adhesion layer 48 formed on the first surface 44, the second surface 46, or both can be in contact with the inorganic layer 100 formed on the first or second, or both surfaces of the substrate 40. Moreover, those skilled in the art will appreciate that the conductive element 50 can interconnect an electronic device on a single sided substrate of electronic circuit.

FIG. 13 illustrates a side view of an electronic display having an electronic circuit fabricated in accordance with the teachings of the present invention. Electronic display 140 includes the substrate 40 having formed on at least one surface the adhesion layer 48 and the conductive element 50. The electronic display 140 also includes display media 130, indium tin oxide (ITO) conductive layer 132, and polyester backing film 134. Suitable display media 130 includes bi-stable electronic inks and liquid crystalline media such as polymer-dispersed liquid crystals. The term “electronic ink” as used herein is intended to include any suitable bi-stable, non-volatile display material. The term “bi-stable” as used herein is intended to indicate that the particles of the imaging material can alternately occupy two stable states.

According to one practice, a microcup® is filled with electrically charged white particles in a black or colored dye. Electrodes can be disposed on, cover, or both opposite sides of the media for use in applying a voltage potential difference across the electronic ink to cause particles within the microcapsules to migrate toward one of the electrodes. This migration can change the color of the microcup, and hence the pixel location, as viewed by an individual. One example of an electronic display 140 and other examples of display media 130 are discussed in detail in U.S. Pat. No. 6,753,830, entitled “Smart Electronic Label Employing Electronic Ink”, the contents of which are incorporated hereby incorporated by reference. Another example of an electronic display 140 and other examples of display media 130 are discussed in detail in U.S. Provisional Application Ser. No. 60/550,091, filed Mar. 1, 2004, the contents of which are hereby incorporated by reference.

Those skilled in the art will recognize the term microcup® refers to one or more electrophoretic display cells having a structure as disclosed in U.S. Pat. No. 6,753,067, entitled “Microcup Compositions Having Improved Flexure Resistance And Release Properties”, the contents of which are hereby incorporated by reference.

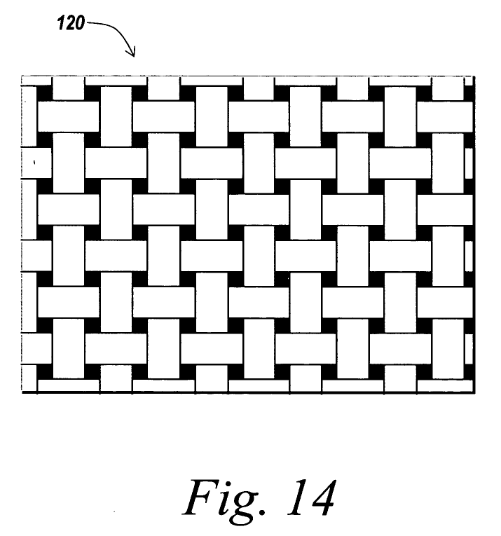

FIG. 14 illustrates a fabric material 120 suitable for use as a substrate 40 in accordance with the teachings of the present invention. Fabric material 120 can be a woven fabric as illustrated and as such graphical and textual designs formed with application 28 can be transferred to the fabric material 120 using the image forming apparatus 14A or 14B and metallized to provide a decorative image on clothes or other goods, such as furniture, drapery, linens, towels, headwear, footwear and other like products that use fabric.

The electrophotographic imaging techniques disclosed herein are well suited for use in forming a thin film transistor array on a flexible polymeric substrate, such as a flexible polyimide substrate. Those skilled in the art will appreciate that the formation of the thin film transistor array can be performed with or without the use of the adhesion layer discussed above in relation to FIGS. 1-14. A thin film transistor array formed in accordance with the teachings of the present invention is well suited for use as an active backplane for addressing an electronic display, such as a liquid crystal display or any other suitable display medium.

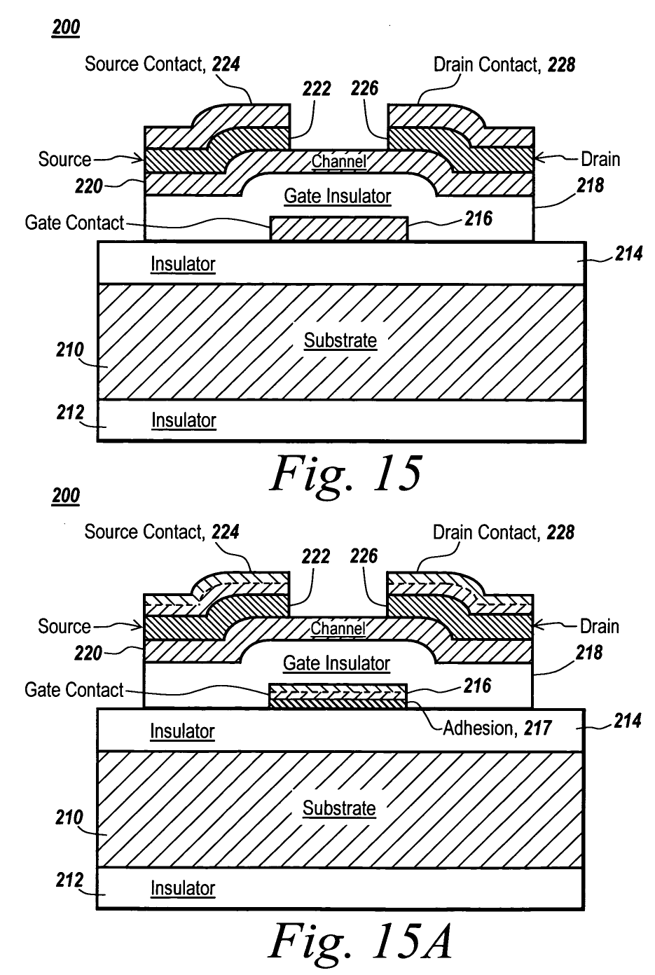

FIG. 15 depicts a side view of a transistor formed in accordance with the teachings of the present invention. Transistor 200 includes a first insulator 212, a substrate 210, a second insulator layer 214, a metallized contact gate 216, a gate insulator layer 218, a channel layer 220, a source 222, a drain layer 226, a metallized source contact 224 and a metallized drain contact 228. A first surface of the flexible polymeric substrate 210 contacts a first surface of the first insulator layer 212. A second surface of the flexible polymeric substrate 210 contacts a first surface of the second insulator layer 214. A second surface of the insulator layer 214 contacts a first surface of the metallized gate contact 216 and a first surface of the gate insulator layer 218. A second surface, third surface, and fourth surface of the metallized gate contact 216 each contact a surface of the gate insulator layer 218.

A second surface of the gate insulator layer 218 contacts a first layer of the channel layer 220. A first portion of a second surface of the channel 220 contacts a first surface of the source 222. A second portion of the second surface of the channel 222 contacts a first surface of the drain 226. A second surface of the source 222 contacts a first surface of the metallized source contact 224. A second surface of the drain 226 contacts a first surface of the metallized drain contact 228.

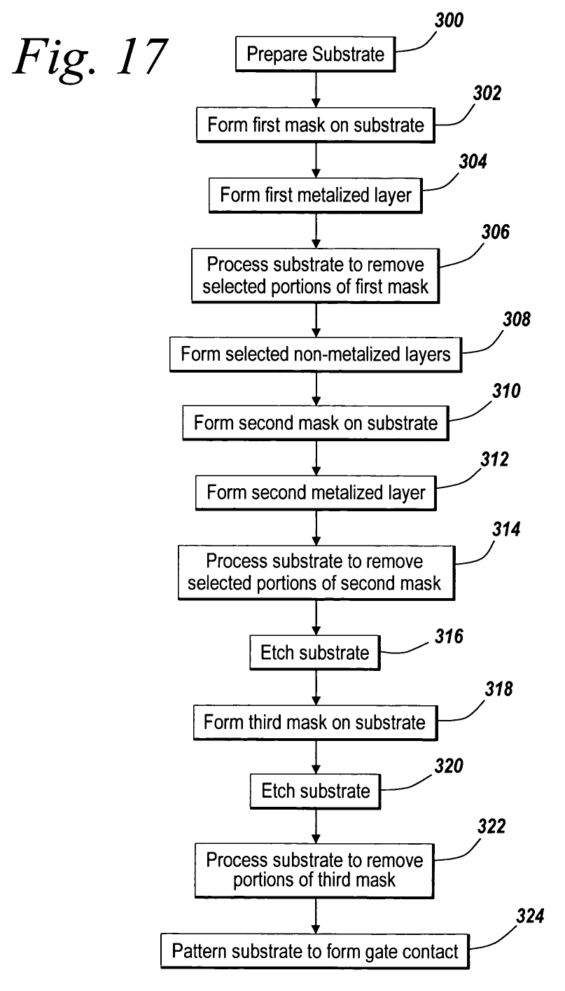

Formation of the transistor 200 is discussed in more detail with relation to FIG. 17.

One suitable material for the flexible polymeric substrate 210 is Kapton® E having a thickness of about 51 μm. Other suitable materials include high performance polymers such as polybenzimidazole, polyethylene naphthalate, polyethylene terephthalate, or lignocelluloses. The first insulator layer 212 and second insulator layer 214 form barrier layers or subbing layers to isolate the flexible polymeric substrate 210 from the remainder of the transistor 200. The first insulator layer 212 and the second insulator layer 214 provide a moisture barrier for the flexible polymeric substrate 210 and assist in providing dimensional stability and a base with good adhesion properties during manufacture of the transistor 200 or an array of transistors 200 on the flexible polymeric substrate 210. The first insulator layer 212 and the second insulator layer 214 are each formable using silicon nitride (SiNₓ). A suitable thickness for the first insulator layer 212 formed of SiNₓ is about 500 nm. In similar fashion, a suitable thickness for the second insulator layer 214 formed of SiNₓ is about 500 nm. The of each insulator layer 212, 214 can have a thickness that ranges from about 50 nm to 2000 nm.

The gate insulator layer 218 is formable from SiNₓ having a thickness of between about 20 nm and about 1000 nm. In one embodiment of the present invention the gate insulator layer 218 is formed from SiNₓ with a thickness of about 360 nm.

The channel layer 220 is formable using amorphous silicon (a-Si) with a thickness of between about 100 nm and about 400 nm. One type of amorphous silicon suitable for forming the channel layer 220 is undoped hydrogenated amorphous silicon (a-Si:H) having a thickness of about 200 nm.

The source layer 222 and the drain layer 226 are formable using an n-type amorphous silicon (n⁺) a-Si with a thickness of between about 2.5 nm and about 100 nm. In one embodiment of the present invention the source layer 222 and the drain layer 226 are formed from an n-type phosphorous doped hydrogenated amorphous silicon (n⁺) a-Si:H having a thickness of about 50 nm.

The metallized gate contact layer 216, the metallized source contact layer 224 and the metallized drain contact layer 228 are formable using metals such as chromium (Cr), titanium (Ti), gold (Au), nickel (Ni), aluminum (Al), copper (Cu), silver (Ag), or other suitable material or compound having properties or a structure well suited for a contact layer. Suitable thicknesses of the metallized layers 216, 224, and 228 range between about 10 nm and about 120 nm. The metallized layer 216 can consist of several layers as illustrated in FIG. 15A. In a preferred embodiment, the metallized layer 216 consists of three layers, a 10 nm Cr layer followed by 100 nm Ti, and finally 10 nm of Cr. In this example the bottom layer of Cr serves as an adhesion layer to the insulator layer 214. Such an adhesion layer is discussed above in relation to FIGS. 1-14.

FIG. 15A illustrates the transistor 200 having an adhesion layer 217 formed between a first surface of the metallized gate contact layer 216 and a second surface of the second insulator layer 214. The adhesion layer 217 is formable in accordance with steps 60-72 discussed in relation to FIG. 8 above. FIG. 15A further illustrates the metallized source and drain contact layers 224 and 228 are formable to include multiple metallized layers.

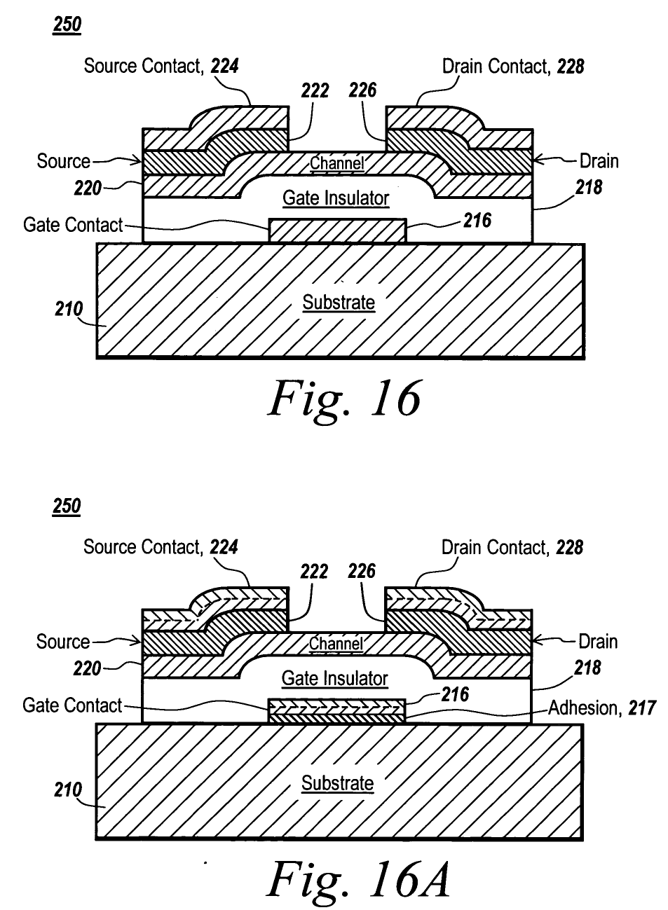

FIG. 16 illustrates a side view of another transistor formed in accordance with the teachings of the present invention. Transistor 250 includes the flexible polymeric substrate 210, the metallized gate contact layer 216, the gate insulator layer 218, the channel layer 220, the source layer 222, the drain layer 226, the metallized source contact layer 224, and the metallized drain contact layer 228. Formation of the transistor 250 is discussed in more detail below with regard to FIG. 17.

The gate insulator layer 218 is formable from SiNₓ having a thickness of between about 20 nm and about 1000 nm. In one embodiment of the present invention the gate insulator layer 218 is formed from SiNₓ with a thickness of about 360 nm.

The channel layer 220 is formable using amorphous silicon (a-Si) with a thickness of between about 100 nm and about 400 nm. One type of amorphous silicon suitable for forming the channel layer 220 is undoped hydrogenated amorphous silicon (a-Si:H) having a thickness of about 200 nm.

The source layer 222 and the drain layer 226 are formable using an n-type amorphous silicon (n⁺) a-Si with a thickness of between about 2.5 nm and about 100 nm. In one embodiment of the present invention the source layer 222 and the drain layer 226 are formed from an n-type phosphorous doped hydrogenated amorphous silicon (n⁺) a-Si:H having a thickness of about 50 nm.

The metallized gate contact layer 216, the metallized source contact layer 224 and the metallized drain contact layer 228 are formable using metals such as chromium (Cr), titanium (Ti), gold (Au), nickel (Ni), aluminum (Al), copper (Cu), silver (Ag), or other suitable material or compound having properties or a structure well suited for a contact layer. Suitable thicknesses of the metallized layers 216, 224, and 228 range between about 10 nm and about 120 nm. The metallized layer 216 can consist of several layers. In a preferred embodiment, the metallized layer 216 consists of three layers: a 10 nm Cr layer followed by 100 nm Ti, and finally 10 nm of Cr. In this example the bottom layer of Cr is serving as an adhesion layer to the insulator layer 214. Such an adhesion layer is discussed above in relation to FIGS. 1-14.

FIG. 16A illustrates the transistor 250 having an adhesion layer 217 formed between a first surface of the metallized gate contact layer 216 and a surface of the flexible polymeric substrate 210. The adhesion layer 217 is formable in accordance with steps 60-72 discussed in relation to FIG. 8 above. FIG. 16A further illustrates that each of the metalized contact layers 216, 224, and 228 are formable to include more than one metallized layer.

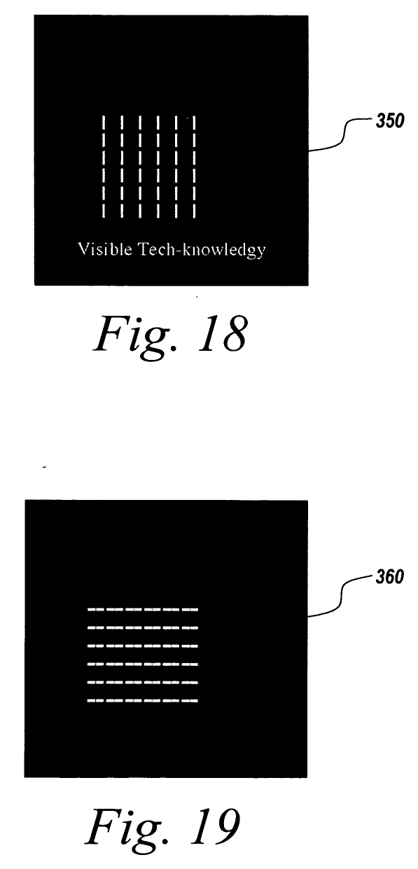

FIG. 17 provides a block flow diagram of steps taken to form a transistor or an array of transistors in accordance with the teaching of the present invention. FIG. 17 is discussed in relation to FIGS. 15, 16, and 18-21.

In step 300, the flexible polymeric substrate 210 is prepared by completing of one or more cleaning operations, completing a PECVD operation to form the first and second insulator layers 212 and 214, respectively, and if necessary completing an operation to dimension the flexible polymeric substrate 210 to a desired dimensionality. Those skilled in the art will appreciate that the one or more cleaning operations can include cleaning with acetone or other suitable cleaning compound followed by a drying operation. Furthermore, those skilled in the art will appreciate that the cleaning operation can include a step or steps to etch one or more surfaces of the flexible polymeric substrate 210 to attain a desired surface texture or surface topology.

If necessary, in step 300, the flexible polymeric substrate 210 is aligned and temporarily affixed to a stiffener element to support the flexible polymeric substrate 210 during formation of a mask on a surface of the substrate by the image forming apparatus 14A or 14B. One suitable stiffener includes a paper medium having a suitable stiffness and predefined alignment marks for aligning the flexible polymeric substrate 210 with the stiffener. Other mediums having a suitable stiffness for feeding into an image forming apparatus are well suited for us as a stiffener.

In step 302, the flexible polymeric substrate 210, with or without the stiffener element is fed into the image forming apparatus 14A or 14D, such as a Lexmark Optra S 1255 Laser Printer available from Lexmark International, Inc., of Lexington, Ky. The flexible polymeric substrate 210, with or without the first insulator layer 212 or the second insulator layer 214, is imaged with electrophotographic imaging compound by the image forming system 14A or 14B to form a negative first mask. The first mask defines the metallized gate contact layer 216.

FIG. 8 illustrates a negative first mask 350 suitable for use in forming an array of metallized gate contact elements 216 on the flexible polymeric substrate 210.

In step 304, a 10 nm layer of Cr, a 100 nm layer of Ti, and 10 nm layer of Cr are deposited by electron beam evaporation under vacuum on the electrophotographic imaging compound pattern provided by the first mask 350 to form a first metallized layer. Those skilled in the art will appreciate that the first metallized layer is formable from a single metal. The total thickness of the first metallized layer can be between about 10 nm and about 2000 nm. In step 306, the flexible polymeric substrate 210, which includes the layers of metal and the first mask 350 formed of the electrophotographic imaging compound is placed in an ultrasonic toluene bath and agitated for about one minute. The ultrasonic bath is repeated as needed and the flexible polymeric substrate 210 is washed with 1,1,1-trichloroethane to quantitatively remove selected portions of the electrophotographic imaging compound and overlying metal layers. Removal of the electrophotographic imaging compound and overlying metal layers reveals the metallized gate contact 216.

Those skilled in the art will recognize there exist a number of suitable cleaning techniques to remove the mask of electrophotographic imaging compound and the selected overlying layer or layers of metal after the formation of the first metallized layer. Examples of cleaning techniques include, but are not limited to, ultrasonic cleaning, rubbing with a swab, and pulse jet sprays. Furthermore, any or all of these techniques can be used alone or in combination with solvents such as 1,1,1-trichloroethane (TCE), solvents from the ketone group, such as acetone, and the like.

In step 308, the flexible polymeric substrate 210 undergoes a deposition process to form the gate insulator layer 218, the channel layer 216, the source 222, and the drain 226. For example, the flexible polymeric substrate 210 is placed in a suitable work piece holder associated with a PECVD system and coated with a layer of SiNₓ having a thickness of about 360 nm to form the gate insulator layer 218; coated with a layer of undoped a-Si:H having a thickness of about 200 nm to form the channel layer 220; and coated with a layer of phosphorous doped n-type hydrogenated amorphous silicon ((n⁺)a-Si:H) having a thickness of about 50 nm to form a conductive layer for the source 222 and the drain 226. Those skilled in the art will appreciate that the layer thicknesses are not meant to be limiting of the present invention and other suitable thicknesses are well within the scope of the present invention. For example, the SiNₓ layer can range in thickness from between about 20 nm and about 1000 nm, the a-Si:H layer can range in thickness from between about 100 nm and about 400 nm, and the (n⁺) Si:H layer can range in thickness from between about 2.5 nm and about 100 nm.

In step 310, a second mask of electrophotographic imaging compound is formed on the flexible polymeric substrate 210 and the various layers already formed thereon. That is, if necessary, the flexible polymeric substrate 210 is temporarily attached and aligned to a stiffener element, for example, a paper medium with predefined alignment marks for aligning the flexible polymeric substrate thereto or temporarily affixed to another suitable medium with predefined alignment markings. The flexible polymeric substrate 210 and the various layers already formed thereon is imaged by the imaged forming apparatus 14A or 14B with electrophotographic imaging compound to form the second mask defining the metallized source contact 224 and the metallized drain contact 228.

FIG. 19 depicts an exemplary second mask 360 suitable for use in defining the metallized source contact 224 and the metallized drain contact 228.

In step 312, a second metallized layer is formed. That is, the flexible polymeric substrate 210 and the various layers formed thereon is placed in an electron beam metal evaporator, such as the system discussed in relation to FIG. 2 above, and a layer of Ti having a thickness of about 100 nm and a layer of Cr having a thickness of about 10 nm are deposited on the second mask of electrophotographic imaging compound to form the metallized source contact 224 and the metallized drain contact 228. Those skilled in the art will appreciate that the metallized source contact 224 and the metallized drain contact 228 are formable from a single layer of metal or may include more than two metallized layers. The metallized source contact layer 224 can be metallized drain contact layer 228 can have an overall layer thickness of between about 10 nm and about 2000 nm.

In step 314, the flexible polymeric substrate 210 with the second metallized layer formed thereon is processed to remove selected portions of the second mask and overlying metal layer or layers. To remove selected portions of the second mask and overlying metallized layer or layers the flexible polymeric substrate 210 is placed in an ultrasonic toluene bath and agitated for about 1 minute. The ultrasonic bath is repeated at least once and the flexible polymeric substrate 210 is washed with TCE to quantitatively remove selected portions of the electrophotographic imaging compound forming the second mask and overlying metal layers to reveal the metallized source contact 224 and the metallized drain contact 228.

After drying, the flexible polymeric substrate 210 and the various layers formed thereon are etched in step 316. In step 316, the flexible polymeric substrate 210 with the various layers formed thereon is placed in a plasma etcher, such as the Plasma-Therm 790 System VII to remove a portion of the (n⁺) a-Si:H layer formed on the channel layer 220 to expose a portion of the channel layer 220 and form the source 222 and the drain 226. Those skilled in the art will appreciate that the metallized source contact 224 and the metallized drain contact 228 act like a mask in step 316 defining the source 222 and the drain 226 by the protecting the underlying (n⁺) a-Si:H from being etched. Suitable etching conditions are 150 mbar, 16 standard cubic centimeters/minute CF₄, and 0.12 watts per centimeter squared for a total of about 7 minutes.

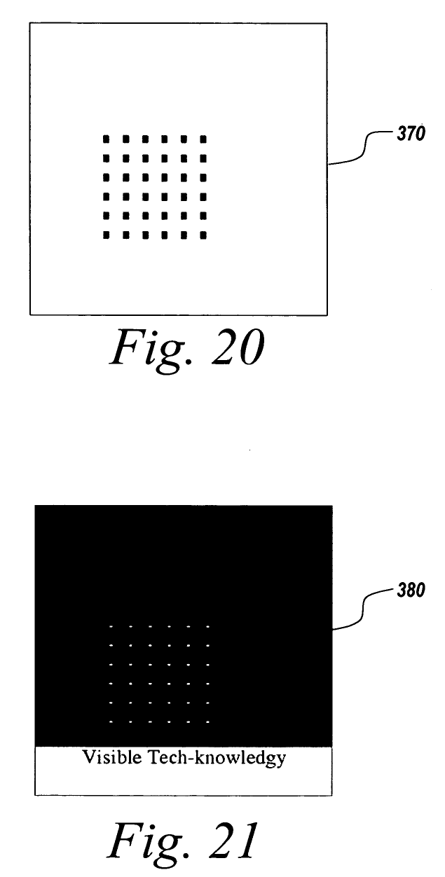

In step 318, a third mask of electrophotographic imaging compound is formed on the flexible polymeric substrate 210 and the various layers formed thereon to define a transistor island or an array of transistor islands on the polymeric substrate 210. FIG. 20 includes an exemplary third mask 370 suitable for use to define a plurality of transistor islands on the flexible polymeric substrate 210. The third mask is formed on the polymeric substrate 210 and the various layers formed thereon by again, if necessary, temporarily affixing the polymeric substrate 210 to a suitable stiffener element having predefined alignment marks and imaging the flexible polymeric substrate 210 with the various layers formed thereon in the image forming apparatus 14A or 14B to form a mask of electrophotographic imaging compound.

In step 320, the flexible polymeric substrate 210 and the various layers formed thereon is etched to remove portions of the channel layer 220. A suitable methodology for etching the channel layer 220 includes a plasma etcher, such as the Plasma-Therm 790 System VII. Suitable etching conditions include, but are not limited to 150 mbar 16 standard cubic centimeters/minute CF₄ and 0.12 watts per centimeter squared until a sufficient amount of the channel layer 220 is removed to a plurality of transistors electrically isolated from one another.

In step 322, the flexible polymeric substrate 210 is cleaned to remove the remaining electrophotographic imaging compound layer formed with the third mask 370. Suitable cleaning methodologies include toluene in an ultrasonic cleaning bath.

At this point in the process an array of transistors are defined on the flexible polymeric substrate 210 by the above defined steps.

In step 324, the flexible polymeric substrate 210 and the various layers formed thereon is coated with photoresist. The photoresist coated flexible polymeric substrate 210 is exposed to ultraviolet light using conventional photolithography using an exemplary mask 380 shown in FIG. 21. Reactive ion etching (RIE) technique is used to form a window in the gate insulator layer 218 and expose the metallized gate contact layer 216. FIG. 21 depicts an exemplary mask 380 suitable for use in exposing the metallized gate contact layer 216. One suitable RIE technique to remove the SiNₓ of the gate insulated layer 220 exposed in the photoresist window formed by the mask 380 is through the use of a Plasma-Therm 790 System VII at 100 mbar, 35 standard cubic centimeters/minute of CF₄, 5 standard cubic centimeters/minute of O₂, and 0.16 watts per centimeter squared, for about 8 minutes. The remaining photoresist of the fourth mask 380 is removed using acetone in an ultrasonic cleaning bath or other suitable means.

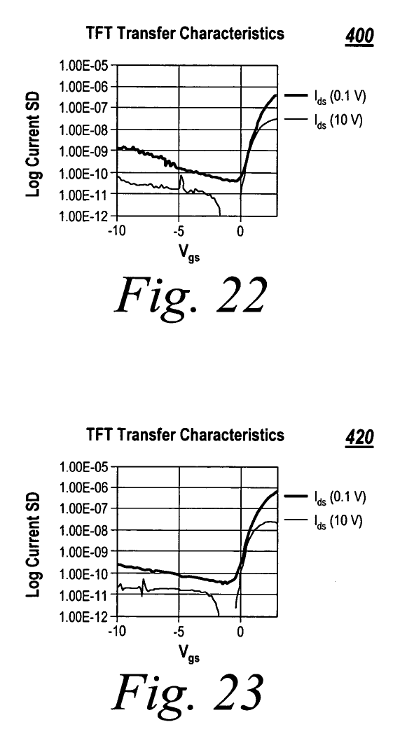

FIG. 22 graphically depicts source-drain current as a function of voltage between the gate and source of a transistor formed in accordance with the teachings of the present invention. The thin film transistor transfer characteristics depicted in graph 400 represent the characteristics of the transistor 200 with the first insulator layer 212 and the second insulator layer 214. The lower trace in the graph 400 represents the drain-source current of the transistor 200 for the condition that the source-drain voltage difference is held at 0.1 V DC. The upper trace in the graph 400 represents the drain-source current when the voltage between the source and drain is held at 10 V DC.

FIG. 23 graphically illustrates the thin film transfer characteristics of the transistor 250 illustrated in FIG. 16. The graph 420 includes an upper trace representing the drain-source current when the voltage difference between the source-drain is held at 10 V DC. The lower trace of the graph 420 represents the drain-source current of the transistor 250 when the drain-source voltage is held at 0.1 V DC.

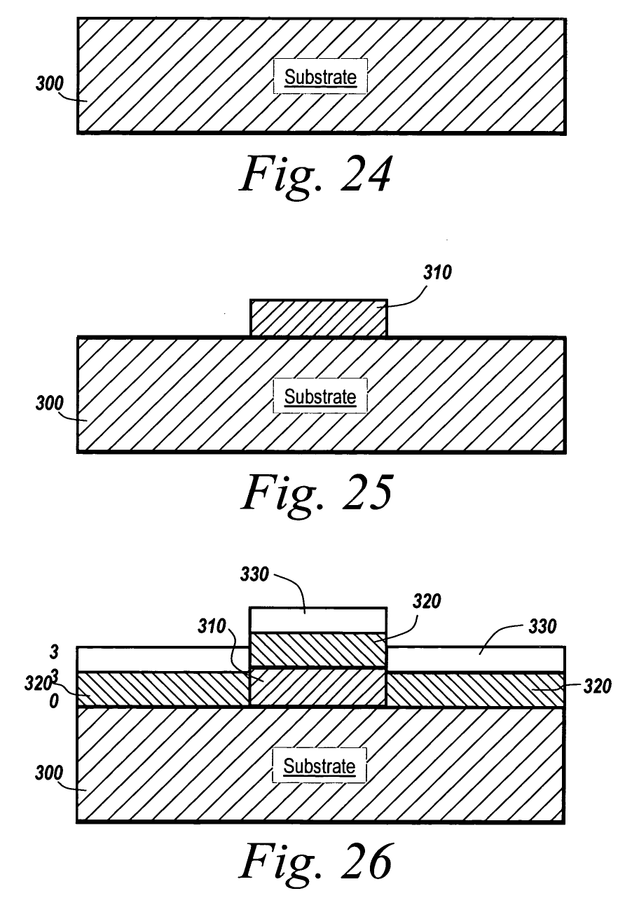

FIG. 24 illustrates a lignocellulosic substrate 400 used to form a conductive pattern thereon in accordance with the teachings of the present invention. As disclosed herein, the lignocellulosic substrate 400 is described in accordance with the teachings of the present invention to form a seven segment display. Formation of the seven segment display is discussed in relation to steps and processes discussed in relation to FIGS. 8 and 9 above. Nevertheless, those skilled in the art will appreciate that other conductor patterns are possible in addition to the seven segment display discussed herein. Such other conductor patterns, which could be employed, are single icon segment, fourteen segment, or teroid multisegment displays.

In accordance with steps 60 and 64 a negative electrophotographic imaging compound pattern consisting of a seven segment display is imaged on the lignocellulosic substrate 400 using the image forming system 14A or 14B, such as a laser printer. One suitable laser-printer is available from Lexmark International, of Lexington, Kentucky under the model Lexmark Optra S1255.

In accordance with step 68, a 10 nm layer of Ti is deposited by electron beam evaporation under vacuum on the electrophotographic imaging compound pattern to form an adhesion layer 420. In accordance with step 70, a conductive layer 430 of Au having a thickness of about 60 nm is deposited on the adhesion layer 420 using electron beam evaporation technology under vacuum.

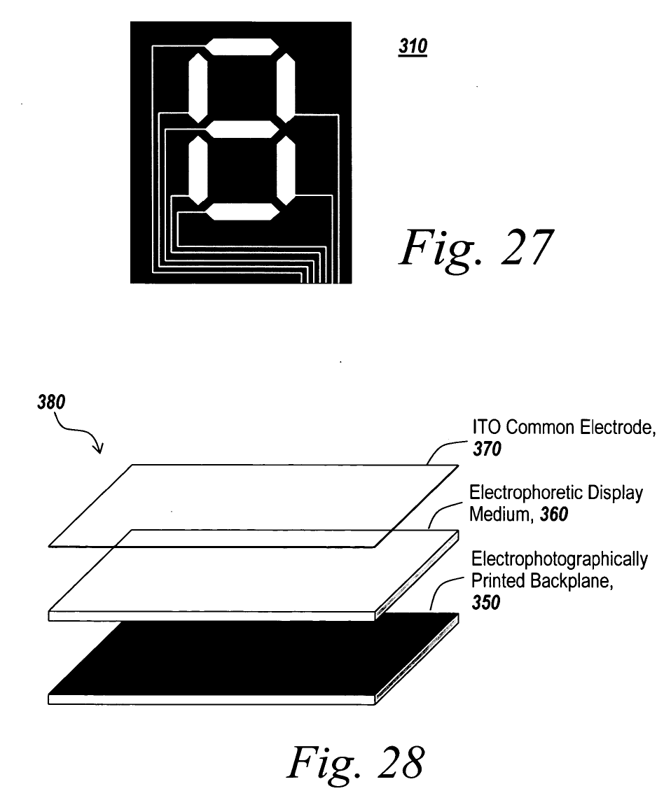

The lignocellulosic substrate 400 is removed from the electron beam system and is cleaned in accordance with step 72 to remove mask 410 and the overlying adhesion layer 420 and conductive layer 430. One suitable cleaning technique is to place the lignocellulosic substrate 400 with the metal layers formed thereon in a bath of TCE and rubbed with a foam brush to remove the electrophotographic imaging compound and overlying unwanted metal layers. If necessary, the rubbing process is repeated with the same or additional solvent to insure removal of the electrophotographic imaging compound and unwanted metal layers. After cleaning, the lignocellulosic substrate 400 is allowed to dry. FIG. 27 provides an exemplary mask 410 used to define a seven segment display on the lignocellulosic substrate 400.

FIG. 28 illustrates a flexible display 480 formed using the lignocellulosic substrate 400. The flexible display 480 includes an electrophotographically printed backplane 450, and electrophoretic display medium 460, and a common electrode 470. The electrophotographically printed backplane 450 includes the lignocellulosic substrate 400 having formed thereon a conductive pattern, for example, the seven segment display depicted by the mask 410. The electrophotographically printed backplane 450 is affixed to electrophoretic display medium 460 using suitable lamination means such as combinations of pressure, temperature, with an adhesive layer. One suitable electrophoretic display medium 460 is available from SiPix Imaging Inc. The electrophoretic display medium 460 available from SiPix Imaging Inc., is based on a microcup® filled with electrically charged white particles in a black or colored dye. Formation of the display 480 includes adhesion of a transparent common electrode consisting of a polymeric substrate such as polyethylene terephthalate with a layer of indium tin oxide (ITO) 470 on the top surface of the electrophoretic display medium 460.

Application of a voltage potential difference of about 50 volts DC across the electrophoretic display medium 460 causes selected particles within the microcups® to migrate toward the common electrode 470. The migration can change the color of a segment formed on the lignocellulosic substrate 400 as viewed by an individual through the common electrode 470.

It will thus be seen that the invention efficiently attains the objects set forth above, amongst those made apparent from the preceding discussion. Since certain changes may be made in the above constructions, for example, additional layers of compounds and materials can be formed in addition to the layers discussed herein, that is, backplanes or electronic devices having a three layer, four layer, a five layer, a six layer, a seven layer, an eight layer, a nine layer, ten layer, eleven layer, construction are well within the scope of the present invention. It is intended that all matter contained in the above description are shown in the accompanying drawings be interpreted as illustrative and not in a limiting sense.

It is also to be understood that the following claims are to cover all generic and specific features of the invention described herein, and all statements are of the scope of the invention which, as a matter of language, might be said to fall therebetween.

1. A method for forming a transistor on a flexible substrate, the method comprising the steps of
imaging the flexible substrate with an image forming apparatus to form a plurality of masks, each of the masks defining one or more features of the transistor; and
forming a gate, a drain, and a source of the transistor on the flexible substrate according to the features defined by the plurality of masks.

2. The method of claim 1, wherein the flexible substrate comprises a flexible polymeric material.

3. The method of claim 1, wherein the flexible substrate comprises a lignocellulosic medium.

4. The method of claim 1 further comprising the step of forming a first insulator layer on a first surface of the flexible substrate.

5. The method of claim 4 further comprising the step of forming a second insulator layer on a second surface of the flexible substrate.

6. The method of claim 1 further comprising the step of removing at least a portion of each of the masks to expose desired features of the transistor.

7. The method of claim 1, further comprising the step of affixing the substrate to a stiffener.

8. The method of claim 1, further comprising the step of forming a plurality of metallized layers on the flexible substrate to form a plurality of contact regions.

9. The method of claim 1, wherein each of the plurality of masks comprises a layer of an electrophotographic imaging compound.

10. The method of claim 1 further comprising the step of forming an adhesion layer on a surface of the flexible substrate.

11. A method for forming an array of transistors, the method comprising the steps of
forming a first metallized layer on a portion of a first surface of a flexible substrate;
forming a first dielectric layer on a portion of the first surface of the flexible substrate and on a plurality of surfaces of the first metallized layer;
forming a first conductive layer on a surface of the first dielectric layer;
forming a second conductive layer on a portion of a surface of the first conductive layer; and
forming a second metallized layer on portions of the second conductive layer.

12. The method of claim 11, further comprising the steps of,
forming a first insulator layer on a first surface of the flexible substrate; and
forming a second insulator layer on a second surface of the flexible substrate.

13. The method of claim 11, wherein the first dielectric layer comprises silicon nitrate (SiNₓ).

14. The method of claim 11, wherein the first conductive layer comprises undoped hydrogenated amorphous silicon (a-Si:H).

15. The method of claim 11, wherein the second conductive layer comprises an n-type hydrogenated amorphous silicon ((n⁺) a-Si:H).

16. The method of claim 12, wherein the first insulator layer and the second insulator layer silicon nitrate (SiNₓ).

17. The method of claim 11, wherein the flexible substrate comprises a flexible polymeric substrate.

18. The method of claim 11 further comprising the step of forming an adhesion layer on a portion of the first surface of the substrate.

19. The method of claim 11 further comprising the step of forming a mask of an electrophotographic imaging compound on the first surface of the flexible substrate to define the first metallized layer.

20. A thin film transistor array formed by the method of claim 11.

21. A method of forming a conductive element on a lignocellulosic substrate, the method comprising the steps of
forming a mask of an electrophotographic compound on the lignocellulosic substrate defining the conductive element; and
forming the conductive element on the lignocellulosic substrate as defined by the mask.

22. The method of claim 21 further comprising the step of forming an adhesion layer on the lignocellulosic substrate as defined by the mask.

23. An electronic circuit comprising,
a lignocellulosic substrate,
an adhesion layer in contact with a portion of a first surface of the lignocellulosic substrate, and
a conductive path in contact with a portion of the adhesion layer, the conductive path coupling a portion of a first electronic device of the electronic circuit to a portion of a second electronic device of the electronic circuit.

24. An electronic display, comprising
an electrophotographically imaged backplane formed on a lignocellulosic substrate,
an electrophoretic display medium coupled to the electrophotgraphically imaged backplane, and
a common electrode coupled to the electrophoretic display medium.

25. The electronic display of claim 24, wherein the electrophoretic display medium comprises, at least one of a bi-stable, non-volatile imaging material, a gyricon material, cholesteric material, a zenithal bi-stable device material, a thermo-chromic material, surface stabilized, ferroelectric liquid crystals, or an electrophoretic material having a plurality of portioned cells, each cell having a plurality of walls and an electrophoretic fluid filled therein.
